(19) United States
(12) Patent Application Publication
(10) Pub. No.: US 2008/0055853 A1
(43) Pub. Date: Mar. 6, 2008

(54) HEAT DISSIPATING MODULE AND ASSEMBLY OF THE HEAT DISSIPATING MODULE AND A COMPUTER HOUSING

(75) Inventors: Shin-Chieh LIN, Taipei Hsien (TW); Ming-Feng Shieh, Taipei Hsien (TW)

Correspondence Address: FOLEY AND LARDNER LLP;SUITE 500, 3000 K STREET NW, WASHINGTON, DC, 20007, US

(73) Assignee: AOPEN INC.

(21) Appl. No.: 11/759,666

(22) Filed: Jun. 7, 2007

(30) Foreign Application Priority Data
Sep. 6, 2006 (TW) 095215829

(51) Int. Cl. H05K 7/20

(52) U.S. Cl. 361/697

(57) ABSTRACT

In an assembly of a heat dissipating module and a computer housing, the computer housing has an interior adapted for receiving an electronic component, and a housing fan. The heat dissipating module includes a heat sink base and a fan. The heat sink base is provided on the electronic component, and the fan is provided on the heat sink base. The heat sink base absorbs heat generated by the electronic component, and the hot air around the heat sink base is drawn in by the fan and discharged directly toward the housing fan, which in turn extracts the hot air out of the computer housing. Thus, hot air around the electronic component is not likely to stay within the computer housing, thereby maintaining a normal operating temperature within the computer housing.

### CROSS-REFERENCE TO RELATED APPLICATION

This application claims priority of Taiwanese Application No. 095215829, filed on Sep. 6, 2006.

### BACKGROUND OF THE INVENTION

1. Field of the Invention

The invention relates to a heat dissipating module and an assembly of the heat dissipating module and a computer housing, more particularly to a heat dissipating module utilizing a fan for heat dissipation and an assembly of the heat dissipating module and a computer housing.

2. Description of the Related Art

Referring to FIGS. 1 and 2, a conventional heat dissipating device 1 used by a central processing unit 13 (hereinafter referred to as CPU) in a computer housing 2 of a computer system is shown to include a heat sink base 12 and an axial current type fan 11. The heat sink base 12 is disposed on an upper side of the CPU 13 for absorbing heat generated by the CPU 13. The axial current type fan 11 is disposed on an upper side of the heat sink base 12 to draw relatively cooler atmospheric air from the outside of the computer housing 2 toward the heat sink base 12 below so as to dissipate the hot air around the heat sink base 12 to thereby achieve the effect of dissipating the heat of the CPU 13.

Referring to FIGS. 2 and 3, the conventional heat dissipating device 1 is generally used in conjunction with a housing fan 21 of the computer housing 2 when disposed within the computer housing 2 of the computer system. The housing fan 21 extracts the hot air which was dispelled to the interior of the computer housing 2 by the heat dissipating device 1 to the outside of the computer housing 2.

However, one disadvantage of providing such heat dissipating device 1 within the computer housing 2 is that, as shown in FIG. 2, since the axial current type fan 11 needs to draw in cooler air from the outside so as to dissipate the heat of the heat sink base 12 below, when the heat dissipating device 1 is disposed within the computer housing 2, a housing wall 22 of the computer housing 2 must be provided with air vents 23 corresponding to an upper side of the axial current type fan 11. These air vents 23 impair the overall appearance of the computer housing 2. Besides, when the outside air is drawn through the air vents 23 by the axial current type fan 11, whistling sounds of the moving air will also create noise. Furthermore, when the axial current type fan 11 blows cooler air toward the heat sink base 12, the hot air is dispersed from the heat sink base 12 to the interior of the computer housing 2. Although there is the housing fan 21 to extract the hot air, the hot air deep within the computer housing 2 and farthest from the housing fan 21 is difficult to be extracted, so that there is constantly some residual hot air remaining in the computer housing 2, which may cause damage to other electronic components.

### SUMMARY OF THE INVENTION

Therefore, an object of the present invention is to provide a heat dissipating module that does not require provision of air vents in a computer housing in which the heat dissipating module is mounted so as to reduce noise.

Another object of the present invention is to provide an assembly of a heat dissipating module and a computer housing, which reduces residual hot air in the computer housing, and which eliminates the need to provide air vents in the computer housing.

Accordingly, the heat dissipating module of the present invention includes a heat sink base and a fan. The heat sink base is adapted to be provided on an electronic component, and has a plurality of heat dissipating fins. The fan is provided on the heat sink base, and includes a casing and a fan rotor disposed within the casing. The casing includes a bottom wall confronting the heat sink base, and a surrounding wall connected to the bottom wall and extending in a direction away from the heat sink base. The bottom wall is provided with an air inlet. The surrounding wall is provided with an air outlet. When the fan rotor rotates, the hot air around the heat sink base is drawn into the casing through the air inlet, and is subsequently discharged through the air outlet in substantially the same direction.

The assembly of the heat dissipating module and the computer housing according to the present invention includes a computer housing, a housing fan, and a heat dissipating module. The computer housing is adapted to receive an electronic component. The heat dissipating module includes a heat sink base and a fan. The heat sink base is provided on the electronic component, and the fan is provided on the heat sink base. The fan includes a casing and a fan rotor disposed within the casing. The casing includes a bottom wall confronting the heat sink base, and a surrounding wall connected to the bottom wall and extending in a direction away from the heat sink base. The bottom wall is provided with an air inlet. The surrounding wall is provided with an air outlet.

When the fan rotor rotates, the hot air around the heat sink base is drawn into the casing through the air inlet, and is subsequently discharged through the air outlet in an air discharge direction. The air discharge direction intersects a portion of the computer housing.

The housing fan is provided on the portion of the computer housing which intersects with the air discharge direction, and has an air intake side facing toward an interior of the computer housing, and an air discharge side facing away from the computer housing. The housing fan draws in air currents discharged by the fan, and discharges the same out of the computer housing through the air discharge side.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view to illustrate a conventional heat dissipating device employed by a central processing unit of a computer system;

FIG. 2 is a partly sectional view to illustrate that the conventional heat dissipating device draws atmospheric air into a computer housing of the computer system;

FIG. 3 is a schematic top view to illustrate the paths of dissipated air during operation of the conventional heat dissipating device;

FIG. 4 is a schematic top view to illustrate a preferred embodiment of an assembly of a heat dissipating module and a computer housing according to the present invention;

FIG. 5 is an assembled perspective view of the heat dissipating module; and

FIG. 6 is an exploded perspective view to illustrate a centrifugal type fan of the preferred embodiment.

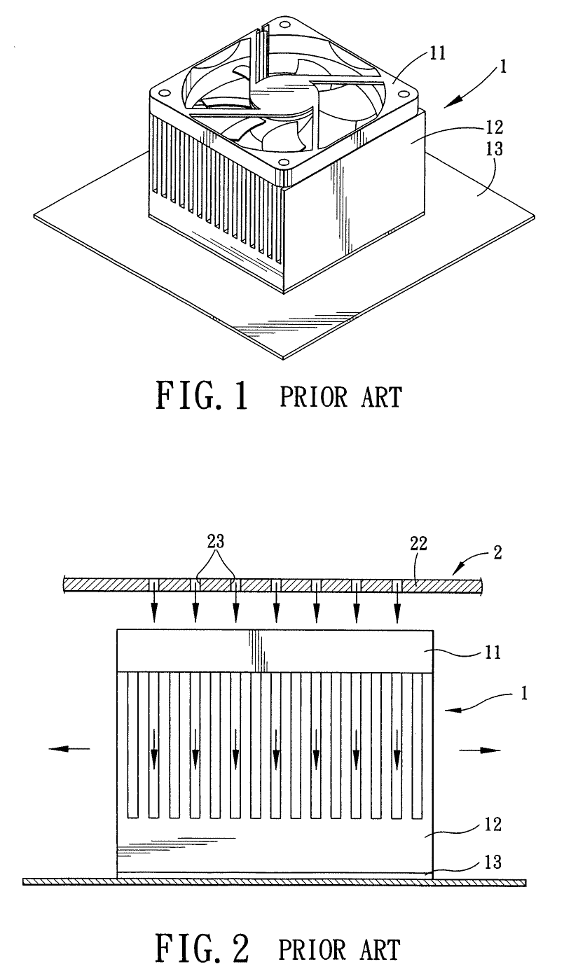

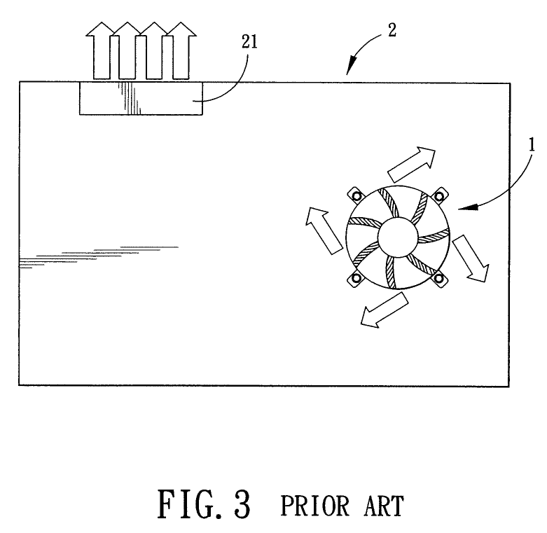

### DETAILED DESCRIPTION OF THE PREFERRED EMBODIMENT

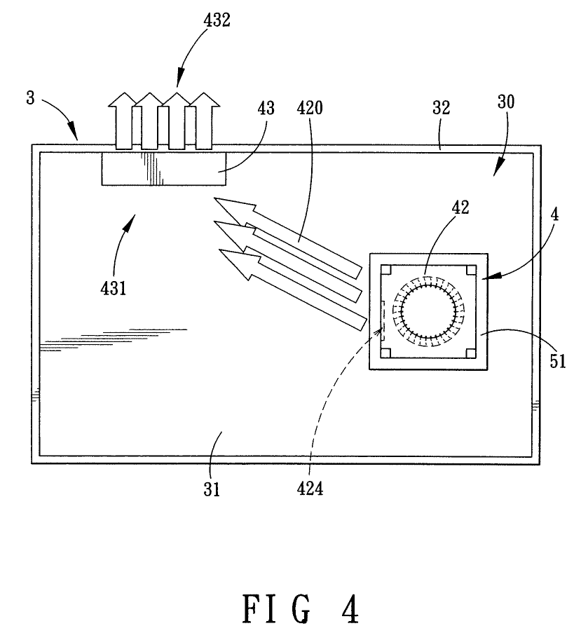

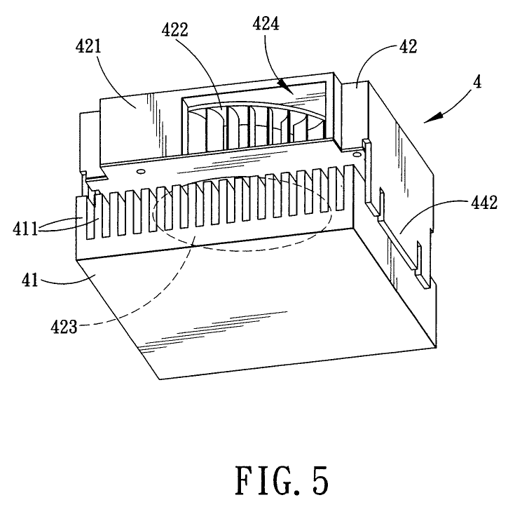

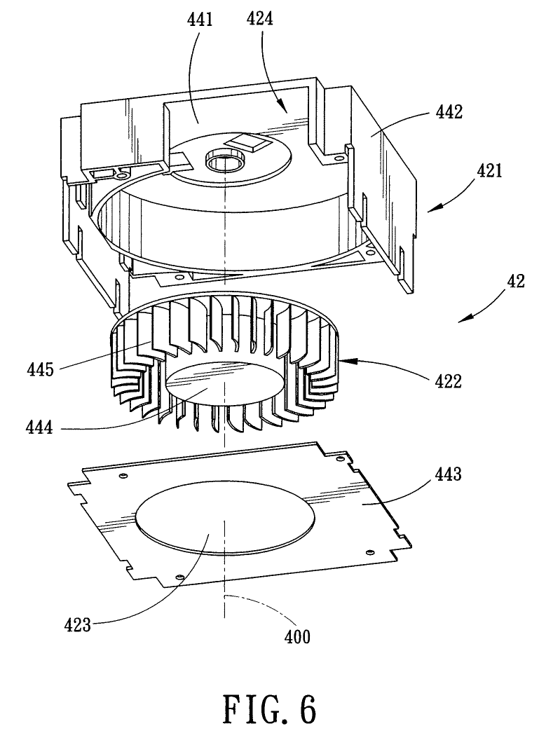

Referring to FIGS. 4 to 6, a preferred embodiment of a heat dissipating module and an assembly of the heat dissipating module and a computer housing is shown to include a computer housing 3, a heat dissipating module 4 disposed within the computer housing 3 and adapted to dissipate heat generated by an electronic component within the computer housing 3, and a housing fan 43.

The computer housing 3 of this embodiment includes a base wall 31 and a surrounding wall 32 which surrounds and is connected to a surrounding outer edge of the base wall 31, and which cooperates with the base wall 31 to define an interior housing space 30 for receiving hardware components, such as a motherboard, a central processing unit (hereinafter referred to as CPU) 51, and other PCI cards. The electronic component referred to in this embodiment is the CPU 51, and the CPU 51 is disposed on the motherboard and the base wall 31.

The heat dissipating module 4 includes a heat sink base 41 and a fan. The fan used in this embodiment is a centrifugal type fan 42. The heat sink base 41 is disposed on the CPU 51, and has a plurality of spacedly arranged heat dissipating fins 411. When the CPU 51 is in operation, the heat generated by the CPU 51 is transferred to the heat sink base 41 through thermal conduction, and the heat dissipating fins 411 dissipate the heat to the ambient air through radiation.

The centrifugal type fan 42 is disposed and secured on the heat sink base 41. The centrifugal type fan 42 used in this embodiment includes a casing 421 and a fan rotor 422 disposed within the casing 421. The casing 421 has a bottom portion provided with an air inlet 423. A lateral sidewall of the casing 421 is provided with an air outlet 424. In this embodiment, the casing 421 includes a top wall 441 and a bottom wall 443 that are spaced apart from each other in a top-and-bottom relationship, and a surrounding wall 442 connected to and disposed between the top and bottom walls 441, 443 and extending in a direction away from the heat sink base 41. The bottom wall 443 of the casing 421 confronts the heat sink base 41. The air inlet 423 is disposed in the bottom wall 443, whereas the air outlet 424 is disposed in the surrounding wall 442. Generally speaking, the air outlet 424 preferably has a width equivalent to one half of the width of the casing 421. Two opposite lateral sidewalls of the casing 421 that are not provided with the air outlet 424 extend downwardly past the bottom wall 443 so as to be assembled to two opposite sides of the heat sink base 41 by snap engagement, adhesives, threaded engagement or any other conventional methods. The fan rotor 422 includes a hub portion 444 and a plurality of fan blades 445 that spacedly surround the hub portion 444. Each of the fan blades 445 has a substantially curved transverse cross-section. A fan axis 400 passing through the hub portion 444 is defined. When the fan rotor 422 rotates, the fan blades 445 rotate about the axis 400. The fan axis 400 extends in a direction perpendicular to the top wall 441 and the bottom wall 443 of the casing 421. That is to say, when the centrifugal type fan 42 of this embodiment is disposed on the heat sink base 41, the fan rotor 422 lies substantially flat on the heat sink base 41, and the fan blades 445 are perpendicular to the top wall 441 and the bottom wall 443.

Accordingly, since air currents are drawn through the air inlet 423 into the centrifugal type fan 42 when the latter is in operation and are discharged through the air outlet 424 by means of the fan rotor 422, if the direction of the air currents coming in through the air inlet 423 is defined as an air intake direction of the centrifugal type fan 42 and the direction of the air currents going out through the air outlet 424 is defined as an air discharge direction 420 of the centrifugal type fan 42, the air intake direction is perpendicular to the air discharge direction 420. To illustrate using FIG. 4, the air intake direction is substantially perpendicular to the view of FIG. 4 and is pointing upward, whereas the air discharge direction 420 is substantially parallel to the view of FIG. 4. Thus, when the centrifugal type fan 42 is provided on the heat sink base 41, the hot air dissipated by the heat sink base 41 can be drawn into the casing 421 through the air inlet 423 using the fan rotor 422, and the hot air can be discharged sidewise from the air outlet 424 in the air discharge direction 420.

The housing fan 43 is an axial current type fan, which is disposed on the surrounding wall 32 of the computer housing 3, and which has an air intake side 431 facing toward the interior of the computer housing 3 and an air discharge side 432 facing away from the computer housing 3. It is noted that, in this embodiment, the air discharge direction 420 of the centrifugal type fan 42 intersects a portion of the surrounding wall 32 of the computer housing 3, and the position of the housing fan 43 on the surrounding wall 32 is located at the intersection between the surrounding wall 32 and the air discharge direction 420. That is, when the centrifugal type fan 42 draws in the hot air around the heat sink base 41 and discharges the same through the air outlet 424, the direction of discharge of the hot air directly faces the air intake side 431 of the housing fan 43 such that the hot air discharged by the centrifugal type fan 42 is directly drawn and discharged to the outside of the computer housing 3, thereby preventing dispersal of the hot air discharged by the centrifugal type fan 42 within the interior of the computer housing 3.

Regarding actual data, the thickness of each heat dissipating fin 411 of the heat sink base 41 used in this embodiment is 1 mm. Every two adjacent heat dissipating fins 411 are spaced apart by a spacing of 1.5 mm. The static voltage of the centrifugal type fan 42 may be within a range from 4.3 to 5 mmH2O. In a test conducted with the centrifugal type fan 42 at a static voltage of 4.3 mmH2O, a rotational speed of 12V 3000 rpm, and an air volume 4 CFM, the resultant noise value was 24 to 28 dB. The noise value was 24 dB when the rotational speed of the centrifugal type fan 42 was 1800 rpm, and the noise value was 28 dB when the rotational speed of the centrifugal type fan 42 was 3000 rpm. The rotational speed of the centrifugal type fan 42 depends on the size of the load of the CPU 51. The above detected noise value was the noise value generated when the entire computer system was in operation. That is, in addition to obtaining a better heat dissipating effect of the computer system, the noise produced during operation of the computer system can be maintained to be within the range from 24 to 28 dB.

It is apparent from the foregoing description that, through the provision of the centrifugal type fan 42 of the present invention, the hot air around the heat sink base 41 can be drawn upward into the centrifugal type fan 42 and then discharged through the air outlet 424 in the same direction as a single volume of air, which is different from the conventional axial current type fan that draws in atmospheric air to be blown toward the heat sink base 41. Consequently, it is unnecessary to provide air vents in the computer housing 3, which not only helps maintain the integrity of the appearance of the computer housing 3 but also eliminates the processing steps of providing air vents in the computer housing 3. Besides, the noise problem associated with the whistling sound of air currents passing through the air vents in the prior art can be eliminated to reduce the noise created by the computer housing 3 as a whole. In addition, by providing the housing fan 43 in the air discharge direction 420 of the centrifugal type fan 42, when the centrifugal type fan 42 discharges the hot air around the heat sink base 41, the hot air can be directly extracted by the housing fan 43 to the outside of the computer housing 3 so that the path of air dissipation of the heat dissipating module 4 is relatively smooth, the heat dissipating effect of the housing fan 43 with respect to the computer housing 3 is enhanced, the normal operating temperature of the interior of the computer housing 3 can be maintained, and the hot air discharged by the heat dissipating module 4 will not disperse and stay in the computer housing 3.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A heat dissipating module adapted to be provided on an electronic component, said heat dissipating module comprising:
a heat sink base adapted to be provided on the electronic component and having a plurality of heat dissipating fins; and
a fan provided on said heat sink base and including a casing and a fan rotor disposed within said casing, said casing including a bottom wall confronting said heat sink base, and a surrounding wall connected to said bottom wall and extending in a direction away from said heat sink base, said bottom wall being provided with an air inlet, said surrounding wall being provided with an air outlet;
hot air around said heat sink base being drawn into said casing through said air inlet and being subsequently discharged through said air outlet in substantially the same direction when said fan rotor is driven to rotate.

2. The heat dissipating module according to claim 1, wherein a direction of an air current flowing in through said air inlet is defined as an air intake direction of said fan, and a direction of the air current flowing out through said air outlet is defined as an air discharge direction of said fan, the air intake direction being perpendicular to the air discharge direction.

3. The heat dissipating module according to claim 1, wherein said bottom wall is located on an upper side of said heat sink base, said casing of said fan further including a top wall spaced apart from and disposed above said bottom wall, said surrounding wall being connected to said top wall and said bottom wall, said fan rotor being located between said top wall and said bottom wall and corresponding to said air inlet in said bottom wall.

4. The heat dissipating module according to claim 3, wherein said fan rotor includes a hub portion and a plurality of fan blades surrounding said hub portion, said fan blades being substantially perpendicular to and being disposed between said top and bottom walls, a fan axis passing through said hub portion being defined such that when said fan rotor rotates, said fan blades rotate about the fan axis, the fan axis extending in a direction perpendicular to said top and bottom walls.

5. The heat dissipating module according to claim 1, wherein said air outlet has a width that is approximately one half of that of said casing of said fan.

6. An assembly of a heat dissipating module and a computer housing, comprising:
a computer housing with an interior adapted for receiving an electronic component;
a heat dissipating module including
a heat sink base adapted to be provided on the electronic component and having a plurality of heat dissipating fins, and
a fan provided on said heat sink base and including a casing and a fan rotor disposed within said casing, said casing including a bottom wall confronting said heat sink base, and a surrounding wall connected to said bottom wall and extending in a direction away from said heat sink base, said bottom wall being provided with an air inlet, said surrounding wall being provided with an air outlet, hot air around said heat sink base being drawn into said casing through said air inlet and being subsequently discharged through said air outlet in an air discharge direction when said fan rotor is driven to rotate, the air discharge direction intersecting a portion of said computer housing; and
a housing fan provided at the portion of said computer housing which intersects with the air discharge direction and having an air intake side facing toward the interior of said computer housing and an air discharge side facing away from said computer housing.

7. The assembly according to claim 6, wherein a direction of an air current flowing in through said air inlet is defined as an air intake direction of said fan, and a direction of the air current flowing out through said air outlet is defined as the air discharge direction of said fan, the air intake direction being perpendicular to the air discharge direction.

8. The assembly according to claim 6, wherein said computer housing includes a base wall and a surrounding wall connected to an outer periphery of said base wall, the electronic component being disposed on said base wall, said housing fan being disposed on said surrounding wall.

9. The assembly according to claim 6, wherein said casing of said fan further includes a top wall spaced apart from and disposed above said bottom wall, said surrounding wall being connected to and disposed between said top wall and said bottom wall, said fan rotor being located between said top and bottom walls.

10. The assembly according to claim 9, wherein said fan rotor includes a hub portion and a plurality of fan blades surrounding said hub portion, said fan blades being substantially perpendicular to and being disposed between said top and bottom walls, a fan axis passing through said hub portion being defined, said fan blades rotating about said fan axis when said fan rotor rotates, said fan axis being perpendicular to said top wall and said bottom wall.

11. The assembly according to claim 6, wherein said housing fan is an axial current type fan, and said fan is a centrifugal type fan.

12. The assembly according to claim 11, wherein said centrifugal type fan has a static voltage within a range from 4.3 mmH20 to 5 mmH20.

13. The assembly according to claim 6, wherein each of said heat dissipating fins has a thickness of 1 mm, and a spacing between every two of said heat dissipating fins is 1.5 mm.

14. The assembly according to claim 6, wherein said air outlet has a width that is approximately one half of that of said casing.
